(19) United States
(12) Patent Application Publication
(10) Pub. No.: US 2026/0343763 A1
(43) Pub. Date: Oct. 29, 2026

(54) Stand for a Display Screen

(71) Applicant: Sky CP Limited, Isleworth, Middlesex (GB)

(72) Inventors: Edward Snodgrass, Isleworth, Middlesex (GB); William Howe, Isleworth, Middlesex (GB); Jake Wier, Isleworth, Middlesex (GB)

(73) Assignee: Sky CP Limited, Isleworth, Middlesex (GB)

(21) Appl. No.: 19/107,988

(22) PCT Filed: Aug. 30, 2023
(86) PCT No.: PCT/GB2023/052233

§ 371 Date: Feb. 28, 2025

(30) Foreign Application Priority Data
Sep. 1, 2022 (GB) 2212726.0

(51) Int. Cl. H05K 5/02; H04N 5/655

(52) U.S. Cl. CPC H05K 5/0247; H05K 5/0234; H04N 5/655

(57) ABSTRACT

A stand for a display screen comprises a base for supporting the display screen on a surface, and an attachment mount extending from the base for attachment to a display screen. The base comprising a compartment for housing at least one peripheral device, the compartment including an electrical connector for connecting to the at least one peripheral device, and the compartment being changeable between an open and a closed position.

### FIELD OF THE INVENTION

The present invention relates to a stand for a display screen, and particularly to floor stands for display screens such as televisions.

### BACKGROUND OF THE INVENTION

Display screens such as televisions typically have a number of peripheral devices connected to them. These peripheral devices often provide access to additional services and functionalities outside the core functionality of the display screen. For instance, some peripheral devices primarily provide input to the display screen from an external content service provider, whilst other peripheral devices such as external recording devices may also receive input from the display screen. Regardless of type, peripheral devices need to be connected to the display screen, either physically via cables or remotely via communication protocols such as Bluetooth®, and need to be connected to mains power by cabling. The presence of these peripheral devices and their connection to the display screen presents a number of problems.

A first problem is that these multiple peripheral devices need to be sufficiently close to the display screen to be securely and reliably connected to it. Similarly, as the functionality of the peripheral devices relates to the display screen, the user typically wants to co-locate the display screen and the peripheral devices such that there is only a single area of attention to focus on when using and controlling both the display screen and the peripheral devices, for instance using a remote control. Both of these concerns lead to multiple peripheral devices being clustered on and/or around the display screen. This is problematic as it leads to a cluttered and bulky arrangement of peripheral devices which is inconvenient to the user, for instance when needing to move the peripheral devices for cleaning, and is an inefficient use of space.

A second problem is that the accessibility and visibility of these multiple peripheral devices leaves them exposed to damage or tampering, for instance by children. This is particularly problematic as these peripheral devices are typically high value items. The accessibility and visibility of a high value or desirable peripheral device also leaves it vulnerable to theft.

A third problem is that each of the peripheral devices typically requires multiple connecting cables, first to provide power to the peripheral device and second to connect the peripheral device to the display screen. This arrangement leads to a large number of cables in and around the display screen. These exposed cables are problematic for a number of reasons. First because they are potentially dangerous to users, for instance as tripping hazards, or as choking hazards for children. Second because even when no harm is caused to the user, it is possible to inadvertently pull or dislodge the exposed cabling and therefore risk damage to the peripheral devices or display screen, or at least accidentally disconnect the peripheral device and the display screen leading to loss of functionality. Hence the multiple and exposed cabling represents a number of potential failure points.

### STATEMENT OF THE INVENTION

Aspects of the invention are defined by the accompanying claims. Preferred optional features are defined in the dependent claims.

According to an aspect of the invention, there is provided a stand for a display screen, the stand comprising a base for supporting the stand on a surface, and an attachment mount extending from the base for attachment to a display screen, wherein the base comprises a compartment changeable between an open and a closed position whilst at least one peripheral device is housed in the compartment and functionally connected to a display screen attached to the attachment mount. In particular, the at least one peripheral device being functionally connected to the display screen when it is connected to a power supply and connected to the display screen, with at least one connection provided by an electrical connector located in the compartment. As such, embodiments of the present invention may provide for a single convenient location in which to house peripheral devices for connection to a display screen, wherein the peripheral devices are protected from damage and tampering, and wherein the number of exposed cables in the user's environment which the user could accidentally or inadvertently interact with is considerably reduced.

According to another aspect of the invention, there is provided a stand for a display screen, the stand comprising a base for supporting the display screen on a surface, and an attachment mount extending from the base for attachment to a display screen. The base comprises a compartment for housing at least one peripheral device, the compartment including an electrical connector for connecting to the at least one peripheral device, and the compartment being changeable between an open and a closed position. As such, embodiments of the present invention may provide for a single convenient location in which to house peripheral devices for connection to a display screen, wherein the peripheral devices are protected from damage and tampering, and wherein the number of exposed cables in the user's environment which the user could accidentally or inadvertently interact with is considerably reduced.

The electrical connector may be for connecting the at least one peripheral device to a power supply remote from the stand. Optionally, the electrical connector may be connectable to the power supply remote from the stand by a cable which exits the base. Optionally, the electrical connector may comprises at least one mains plug socket.

The electrical connector may be for connecting the at least one peripheral device to a display screen attached to the attachment mount.

The electrical connector may be fixedly mounted within the compartment.

The electrical connector comprises at least one HDMI socket and/or at least one USB socket.

The base may include a gap for allowing the cabling of the electrical connector to pass therethrough and into the compartment. Optionally, the gap may be proximate to the attachment post.

The compartment may be a drawer, the drawer comprising a cavity within the base and a first portion of the base is configured to be slidably movable between an open and a closed position to respectively reveal and conceal the cavity. The electrical connector may be located within the cavity. Optionally, the first portion of the base comprises at least a portion of the upper surface of the base, the front sidewall of the base, and at least a portion of the left and right sidewalls of the base.

The attachment mount may include a manually accessible recess for removably housing cabling for connecting the at least one peripheral device via the electrical connector to a display screen attached to the attachment mount. Optionally, the recess may include at least one tab arranged to restrict the size of the accessible recess in a particular location.

The stand may include a first and a second electrical connector, the first electrical connector may be a first electrical connector, and further comprising a second electrical connector for connecting the at least one peripheral device to a display screen attached to the attachment mount.

The base may include feet made from a material which substantially resists manual movement through friction contact with a surface.

The at least one peripheral device may be a low-profile peripheral device.

The at least one peripheral device may be for providing additional functionality to a display screen, such as providing an input of additional media content.

The display screen may be attached to the attachment mount, and wherein the at least one peripheral device is housed within the compartment and connected to both the electrical connector and to the display screen.

Various embodiments and aspects of the invention are described without limitation below, with reference to the figures.

### BRIEF DESCRIPTION OF THE DRAWINGS

There now follows, by way of example only, a detailed description of preferred embodiments of the present invention, with reference to the figures identified below.

FIG. 1 shows a front perspective view of a stand according to a first specific embodiment, in a closed configuration;

FIG. 2 shows a back perspective view of the stand according to the first specific embodiment;

FIG. 3 shows a side view of the stand according to the first specific embodiment;

FIG. 4 shows a front perspective view of the stand according to the first specific embodiment, in an open configuration;

FIG. 5 shows a top view of a section of the stand according to the first specific embodiment, in use connected to a display screen and in an open configuration;

FIG. 6 shows a rear view of a section of the stand according to the first specific embodiment, in use connected to a display screen;

FIG. 7 shows a rear perspective view of the stand according to the first specific embodiment, in use connected to a display screen.

### DETAILED DESCRIPTION

In the following description, functionally similar parts carry the same reference numerals between figures. Embodiments of the invention are now described, without limitation and by way of example only, with reference to the accompanying drawings.

Embodiments of the invention provide a stand for a display screen such as a television. The stand includes a base portion and an attachment mount portion. The attachment mount portion extends upward from the base portion and is for attachment to a display screen. The base portion is for supporting the display screen on a surface under gravity, such as the floor, and is sufficiently dimensioned to provide support for the stand when it is both connected to and disconnected from a display screen. The stand may be integrated as part of an integral display screen product, or may be a stand-alone modular element for connection to a plurality of display screens.

The base portion of the stand includes a compartment which can house peripheral devices which are functionally connected to a display screen attached to the stand. The compartment includes an electrical connector for providing at least one connection facilitating the functional connection of the peripheral devices to a source of power and/or the display screen. The compartment is suitably dimensioned to accommodate standard peripheral devices, and may in particular be dimensioned to accommodate relatively low-profile peripheral devices, for instance devices of approximately 5 cm in height. The compartment is manually changeable between an open and a closed position, and configured such that a plurality of peripheral devices which are connected to the display screen can be accommodated entirely within the closed compartment whilst still providing their functionality to the display screen. Accordingly, stands according to embodiments of the present invention allow for peripheral devices located within the compartment to be both powered and connected to the display screen regardless of whether the compartment is either open or closed.

Example peripheral devices are devices such as Apple TV® and/or an external hard drive. These peripheral devices each typically need two types of connection to provide their functionality to the display screen: a first connection to receive power, i.e. via a conventional three-prong plug or via USB, and a second connection to the display screen to input to or receive output from the display screen, i.e. via HDMI or USB. Alternatively, some peripheral devices are able to both provide their functionality and receive power through the same connection, e.g. low-powered devices connected to an HDMI or USB socket. Similarly, some peripheral devices are battery powered and may only need a connection to the display screen and not a separate connection to receiver power. As such, the electrical connector included in the compartment can provide at least one electrical connection to the peripheral devices that facilitates the peripheral device in providing its functionality to the display screen. For instance, the electrical connector may provide a power connection and/or a connection to the display screen. Alternatively there may be a plurality of electrical connectors in the compartment providing at least one of a power connection and/or a connector to the display screen. Preferably the peripheral devices are devices which can receive control input via channels which still function whilst the compartment is closed, i.e. via Bluetooth® or Wi-Fi. Other appropriate peripheral devices will be known to the skilled person.

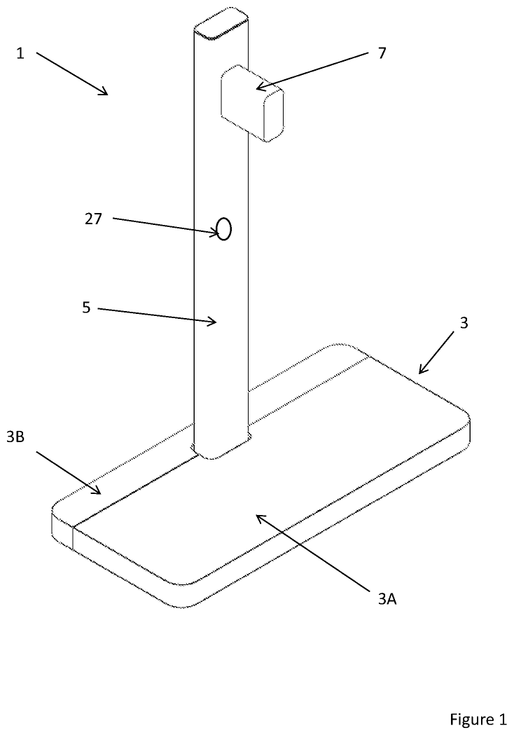

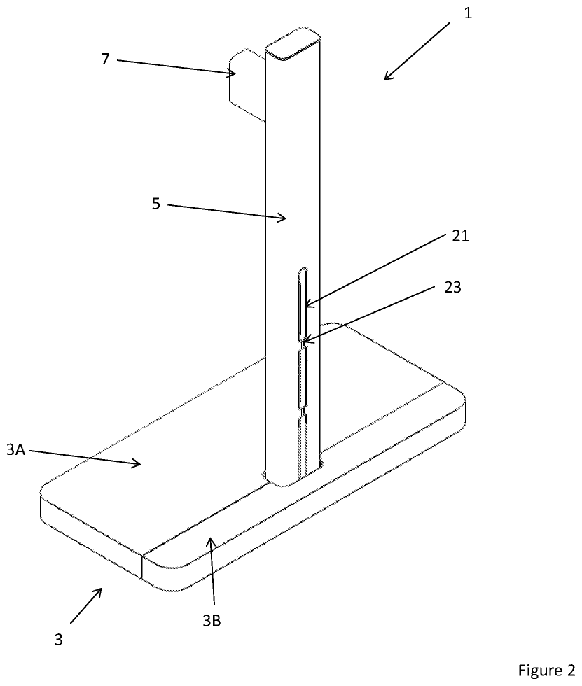

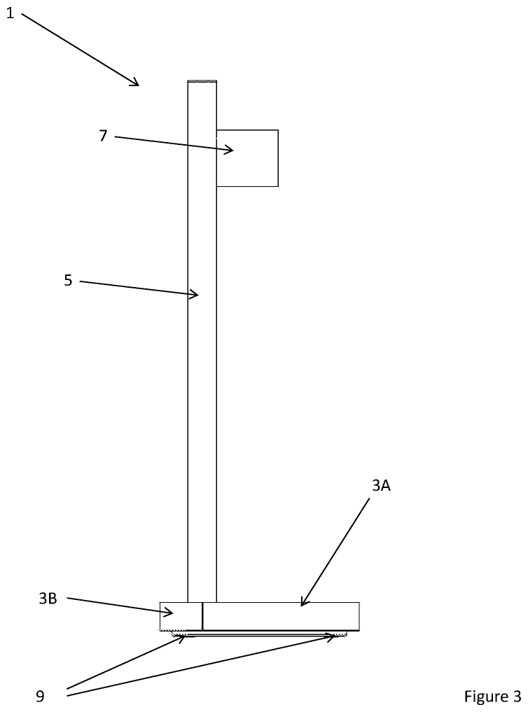

A first specific embodiment of a stand according to the invention is shown in FIGS. 1 to 4. FIG. 1 shows a front perspective view of the stand 1, FIG. 2 shows a back perspective view of the stand 1, and FIG. 3 shows a side view of the stand 1. The stand 1 may be permanently connected to a display screen as an integral part, or may be removably connectable to a plurality of display screens. The stand 1 comprises a base 3 and an attachment mount 5 extending upward away from the base 3. The attachment mount 5 is configured to connect to the display screen. The attachment mount 5 may take any suitable form, such as a pillar or a post or a neck, and for instance may include an arm 7 extending away from the attachment mount 5 for physical connection to the display screen. The base 3 is substantially rectangular and is sufficiently dimensioned to support the stand 1 when connected to the display screen. As shown in FIG. 3, the base 3 may have feet 9 for supporting the stand 1 and for gripping to the surface the stand 1 rests on in use. For instance, the stand 1 may have four feet 9 located near the corners of the underside of the base 3. The feet 9 may be made of a suitable material such as rubber to provide additional grip to the surface on which the base 3 rests. Hence the feet 9 may advantageously provide the base 3 with resistance to movement to allow the stand 1 to be safely manipulated by the user.

The base 3 comprises a manually accessible and operable compartment for housing peripheral devices which can be functionally connected to the display screen. The compartment is movable between an open and a closed position, and is configured such that the peripheral devices can be connected to the display screen, powered and still able to provide their functionality to the display screen even when the compartment is closed.

In the first specific embodiment, the compartment is in the form of a drawer. The base 3 comprises a first section 3A and a second section 3B. The drawer comprises the first section 3A and a cavity 11 internal to the base 3, the cavity 11 formed by the floor 13 of the base 3 and sidewalls 15. The first section 3A is formed of at least a portion of the upper surface 4A of the base 3, the front sidewall 4B of the base 3, and at least a portion of the left and right sidewalls 4C of the base 3. The first section 3A is configured to be slidably movable with respect to the static second section 3B. The floor 13 and the sidewalls 15 are connected to the second section 3B and are static with respect to the first section 3A.

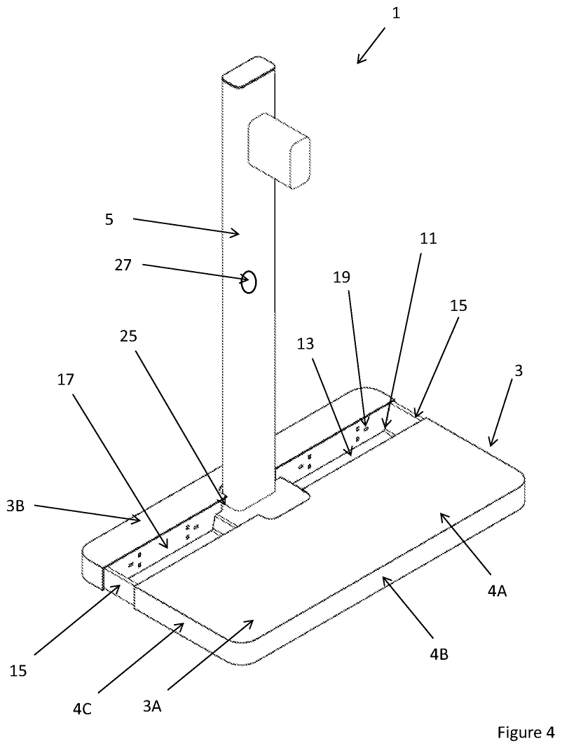

In the open configuration as shown in FIG. 4 the first section 3A is slidably moved away from the static second section 3B such that the internal cavity 11 is revealed and accessible to the user. In the closed configuration as shown in FIG. 1 the first section 3A is slidably moved toward the static second section 3B such that the internal cavity 11 is concealed and inaccessible to the user. The first section 3A of the base 3 may be configured to move along the sidewalls 15 in any conventional manner, for instance through a mutually dimensioned groove and projection contact between the first section 3A and the sidewalls 15, or by rollers or bearings etc. The drawer is suitably dimensioned to accommodate standard peripheral devices, and may in particular be dimensioned to accommodate relatively low-profile peripheral devices. For instance, the height of the internal cavity 11 upward from the floor 13 may be in the region of 5 to 8 cm.

Hence the compartment of embodiments of the present invention may advantageously provide a location in which to safely store peripheral devices associated with the display screen, in particular in a single easy to access location proximate to the display screen, and in a space efficient manner.

Further, the stand of embodiments of the present invention is able to house a plurality of peripheral devices in a manner that advantageously allows and facilitates the peripheral devices to be functionally connected and thereby able to provide their respective functionalities to the display screen whilst the compartment is both open and closed. In particular, the stand according to embodiments of the present invention allows peripheral devices in the compartment to be both powered and connected to the display screen.

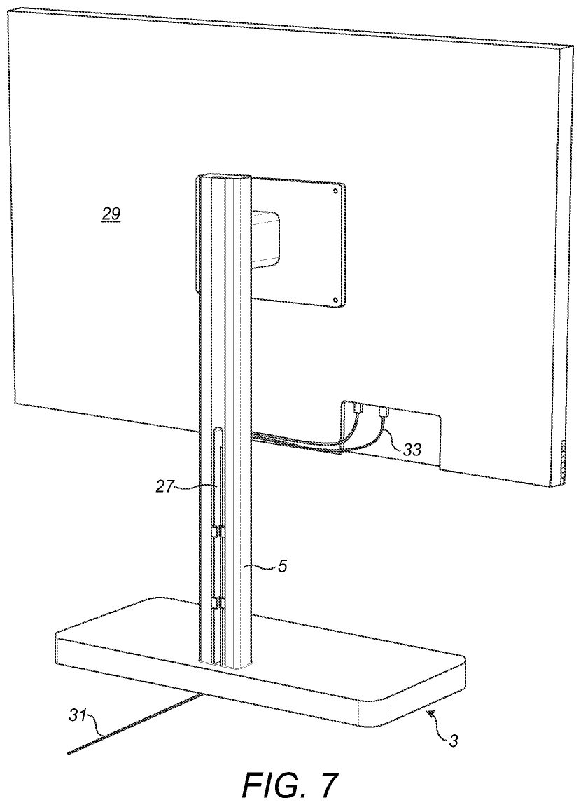

As shown in FIG. 4, in the first specific embodiment the compartment of the base 3 includes at least one electrical connector in the form of a connection hub 17. The connection hub 17 is within the internal cavity 11 and includes means for connecting the peripheral devices to mains power and/or to the display screen. The connection hub 17 may itself receive power from the mains via a single connection cable which exits the stand 1, for instance from a gap or hole located in the base 3, and is connected to the mains. An example mains cable 31 arrangement is shown in FIG. 7, as will be described further below. As shown in FIG. 4, the connection hub 17 may be included in the static second section 3B of the base 3, may be fixedly mounted therein, and may include for instance at least one mains power socket 19. Whilst not depicted, the connection hub 17 may also for instance include a USB socket for delivering power to peripheral devices which are suitably configured.

Accordingly, a plurality of peripheral devices located within the compartment are advantageously able to be powered and functional regardless of whether the compartment is open or closed, or being opened or closed. Hence stands according to embodiments of the present invention may advantageously provide for a reduction in the number of exposed cables in and around the stand, as only a single mains power cable is provided external to the stand which is able to power all of the peripheral devices located within the compartment. This may advantageously reduce the likelihood of injury to users, for instance in accidentally tripping on exposed cabling, and similarly reduce the likelihood of damage to and disconnection of the peripheral devices which would result from accidental interaction with the cabling.

As shown in FIG. 4, in the first specific embodiment the base 3 includes a gap 25 located around the bottom of the attachment mount 5. The gap 25 remains accessible regardless of whether the compartment is either open or closed. The gap 25 may be formed as a cutaway section in the first section 3A and/or second section 3B of the base 3. The gap 25 allows for cabling for connecting the peripheral devices to the display screen, for instance via a second electrical connector which is not depicted here, to run out of the compartment of the base 3 and up to the display screen for connection thereto. In addition or alternatively to the gap 25, as previously mentioned the connection hub 17 may also include means for connecting the peripheral devices to the display screen. For instance, the connection hub 17 may include a relevant socket, such as an HDMI socket, into which the cabling for connecting peripheral devices could be inserted. In such instances the connection hub 17 could include integral cabling internal to the stand 1 which leads up the attachment mount 5 and which can be accessed in the vicinity of the display screen for connection thereto.

Accordingly, a plurality of peripheral devices located within the compartment are advantageously able to be connected to the display screen and functional regardless of whether the compartment is closed, or open, or being opened or closed.

As shown in FIG. 2, in the first specific embodiment the attachment mount 5 may optionally include a recess 21 in which cabling for connecting the peripheral devices to the display screen may be removably inserted. The recess 21 may extend substantially along the length of the attachment mount 5, or may for instance extend up to approximately half way up the attachment mount 5 as shown in FIG. 2, or anywhere in between. The recess 21 may therefore advantageously provide for an easy to use, convenient and space efficient housing of the cables for connecting the peripheral devices to the display screen, for instance via a second electrical connector. This is particularly useful as the user may wish to change peripheral devices from time to time, by either adding or removing new peripheral devices, and hence will benefit from the ease of access and the tidy cable arrangement this provides. Further still, the recess 21 also advantageously reduces the number of exposed cables in and around the stand 1, thereby reducing the likelihood of injury to users and similarly reducing the likelihood of damage to and disconnection of the peripheral devices which would result from accidental interaction with the cabling.

Optionally, the attachment mount 5 may further comprise a hole 27 located on the side of the attachment mount 5 opposite the recess 21, and located at the top of the recess 21. The hole 27 may advantageously allow any cabling within the recess 21 to exit through the front of the attachment mount 5 for easy and convenient access to the respective connectors on the back of the display screen. The recess 21 and the hole 27 may be located sufficiently high up on the attachment mount 5 such that the hole 27 will be behind any display screen connected to the stand 1 such that the cabling is not visible to the user from the front of the display screen.

Optionally, the recess 21 may include tabs 23 which reduce the width of access of the recess 21, and which therefore assist in retaining cables within the recess 21. For instance, the tabs 23 may reduce the width of access to approximately the diameter of a typical cable. There may be a plurality of tabs 23 located along the length of the recess 21.

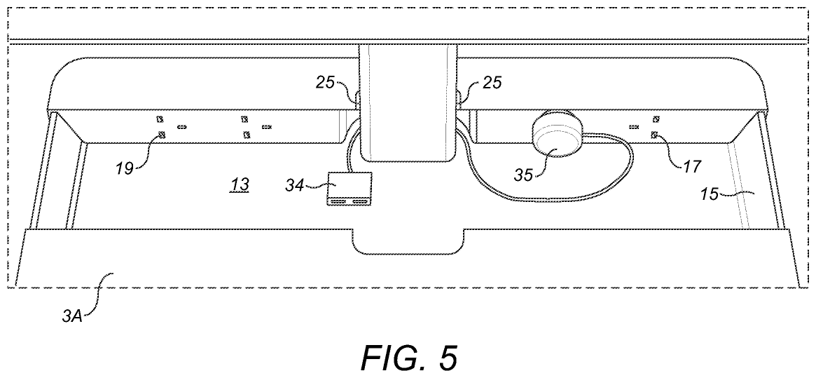

FIGS. 5, 6 and 7 show an example of the stand according to the first specific embodiment in use connected to a display screen 29.

As shown in FIG. 5, when the stand 1 is connected to a display screen 29 the display screen 29 may itself be powered through a power cable 35 connected to the electrical connector in the form of connection hub 17, with the power cable 35 passing through the gap 25 and up to the display screen 29 in any manner as previously described, for instance within the recess 21. This is particularly advantageous in embodiments in which the stand is modular and designed to be removably connected to a plurality of display screens. Further, it is also possible to include a second electrical connector in the form of a display connection socket 34, such as an HDMI socket, within the compartment and into which the cabling for connecting peripheral devices to the display screen 29 could be inserted. In such instances, the cabling for the display connection socket 34 could run from within the compartment and similarly be passed through the gap 25 and up to the display screen 29 in any manner as previously described, for instance within the recess 21. In a specific example, the second electrical connector in the form of a display connection socket 34 could for instance be a splitter including a plurality of inputs, such as HDMI inputs, and capable of automatically selectively outputting content from connected peripheral devices, for instance prioritizing output from one type of peripheral device over another.

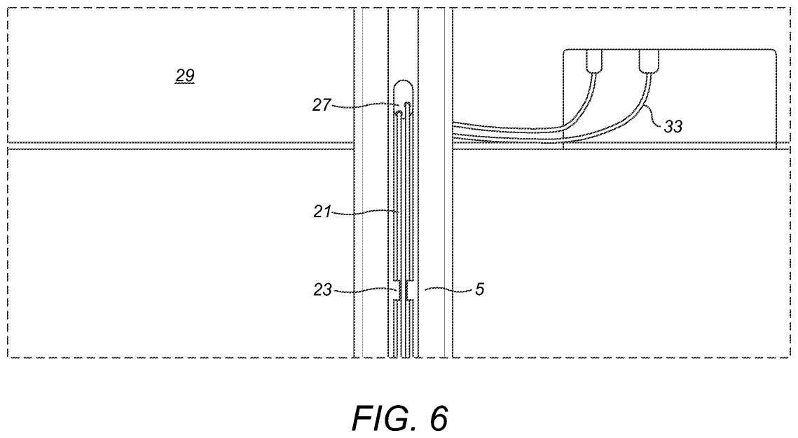

FIG. 6 shows an example of the recess 21 and hole 27 in use containing peripheral device cabling 33 for connecting the peripheral devices in the compartment to the display screen 29. In the specific embodiment depicted, the recess 21 and the hole 27 may be located sufficiently high up on the attachment mount 5 such that the hole 27 is behind the display screen 29 connected to the stand 1 such that the peripheral device cabling 33 is advantageously not visible to the user from the front of the display screen 29.

FIG. 7 shows a rear perspective view of the stand 1 according to the first specific embodiment connected to the display screen 29, wherein at least one peripheral device is functionally connected to the display screen 29 whilst the compartment of the stand 1 is in the closed configuration. Advantageously, there is only a single mains power cable 31 for providing power to the electrical connector in the form of the connection hub 17 internal to the cavity 11 within the base 3, and the peripheral device cabling 33 for connection to the second electrical connector in the form of the display connection socket 34 is advantageously hidden from the front of the display screen 29 and is located within the recess 21. Further, any peripheral devices located within the compartment and functionally connected to the display screen 29 are not visible and are protected from damage by the compartment, whilst still being usable and accessible to the user.

### Alternative Embodiments

The embodiments described above are illustrative of, rather than limiting to, the present invention. Alternative embodiments apparent on reading the above description may nevertheless fall within the scope of the invention.

In alternative embodiments which are not depicted, the compartment may instead take a different form. For instance, in comparison to the first embodiment, the compartment may instead be formed by hinged lid arrangement comparable to a traditional school desk, wherein the first section 3A comprises a lid attached by a hinge to the second section 3B. In such an arrangement, the open configuration would be arrived at by lifting the first section 3A to reveal the internal cavity 11 formed by the floor 13 of the base 3 and the sidewalls 15, and the closed configuration would be arrived at closing the first section 3A to conceal the cavity 11. In this manner, the stand of embodiments of the present invention is able to house a plurality of peripheral devices in a manner that advantageously allows and facilitates the peripheral devices to be able to provide their respective functionalities to the display screen whilst the compartment is both open and closed. In particular, the stand according to embodiments of the present invention allows peripheral devices in the compartment to be both powered and functionally connected to the display screen via at least one electrical connector.

In alternative embodiments which are not depicted, in comparison to the first specific embodiment, instead of the connection hub 17 the means for connection between the peripheral devices and a power supply may for instance be provided by at least one gap or hole located on the back of the base 3, for instance near the attachment mount, which allows the individual power cabling for each of the peripheral devices located within the compartment to be passed therethrough, out of the compartment, and to the external mains plug socket. In this manner a plurality of peripheral devices located within the compartment are advantageously able to be powered and functional regardless of whether the compartment is closed, or open, or being opened or closed.

In alternative embodiments which are not depicted, in comparison to the first specific embodiment, instead of the gap 25 located around the bottom of the attachment mount 5, there may be a gap or hole located elsewhere on the base 3 which allows for cabling for connecting the peripheral devices to the display screen 29 via an electrical connector to run out of the compartment of the base 3 and up to the display screen for connection thereto. Accordingly, a plurality of peripheral devices located within the compartment are advantageously able to be connected to the display screen and functional regardless of whether the compartment is closed, or open, or being opened or closed.

It is noted that certain peripheral devices may be able to be connected to the display screen remotely instead of using cabling. In such instances the peripheral device would simply require power to be supplied to it in line with any of the embodiments described above.

Features of any of the above alternative embodiments may be combined together with the features as described in the first specific embodiment, and/or with each other, in any suitably functional manner.

1. A stand for a display screen, the stand comprising:
a base for supporting the display screen on a surface; and
an attachment mount extending from the base for attachment to a display screen;
the base comprising a compartment for housing at least one peripheral device, the compartment including an electrical connector for connecting to the at least one peripheral device; and
the compartment being changeable between an open and a closed position.

2. The stand of claim 1, wherein the electrical connector is for connecting the at least one peripheral device to a power supply remote from the stand.

3. The stand of claim 2, wherein the electrical connector is connectable to the power supply remote from the stand by a cable which exits the base.

4. The stand of claim 1, wherein the electrical connector comprises at least one mains plug socket.

5. The stand of claim 1, wherein the electrical connector is for connecting the at least one peripheral device to a display screen attached to the attachment mount.

6. The stand of claim 1, wherein the electrical connector is fixedly mounted within the compartment.

7. The stand of claim 1, wherein the electrical connector comprises at least one audio/video socket.

8. The stand of claim 1, wherein the electrical connector comprises at least one power/data socket.

9. The stand of claim 1, wherein the base includes a gap for allowing the cabling of the electrical connector to pass therethrough and into the compartment.

10. The stand of claim 9, wherein the gap is proximate to the attachment post.

11. The stand of claim 1, wherein the compartment is a drawer, the drawer comprising a cavity within the base and a first portion of the base is configured to be slidably movable between an open and a closed position to respectively reveal and conceal the cavity.

12. The stand of claim 11, wherein the electrical connector is located within the cavity.

13. The stand of claim 11, wherein the first portion of the base comprises at least a portion of the upper surface of the base, the front sidewall of the base, and at least a portion of the left and right sidewalls of the base.

14. The stand of claim 1, wherein the attachment mount includes a manually accessible recess for removably housing cabling for connecting the at least one peripheral device via the electrical connector to a display screen attached to the attachment mount.

15. The stand of claim 14, wherein the recess includes at least one tab arranged to restrict the size of the accessible recess in a particular location.

16. The stand of claim 1, wherein the electrical connector is a first electrical connector, and further comprising a second electrical connector for connecting the at least one peripheral device to a display screen attached to the attachment mount.

17. The stand of claim 1, wherein the base includes feet made from a material which substantially resists manual movement through friction contact with a surface.

18. The stand of claim 1, wherein the at least one peripheral device is a low-profile peripheral device.

19. The stand of claim 1, wherein the at least one peripheral device is for providing additional functionality to a display screen, such as providing an input of additional media content.

20. The stand of claim 1, wherein the display screen is attached to the attachment mount, and wherein the at least one peripheral device is housed within the compartment and connected to both the electrical connector and to the display screen.
